(19) United States
(12) Patent Application Publication
(10) Pub. No.: US 2024/0332019 A1
(43) Pub. Date: Oct. 3, 2024

(54) SEMICONDUCTOR HETEROSTRUCTURE AND METHOD OF MANUFACTURING SAME

(71) Applicant: SOCIETE DE COMMERCIALISATION DES PRODUITS DE LA RECHERCHE APPLIQUÉE SOCPRA SCIENCES ET GÉNIE S.E.C., Sherbrooke (CA)

(72) Inventors: Alexandre HEINTZ, Sherbrooke (CA); Bouraoui ILAHI, Sherbrooke (CA); Abderraouf BOUCHERIF, Sherbrooke (CA); Richard ARÈS, Sherbrooke (CA)

(21) Appl. No.: 18/609,763

(22) Filed: Mar. 19, 2024

(30) Foreign Application Priority Data
Mar. 27, 2023 (CA) 3194175

(51) Int. Cl. H01L 21/02; H01L 29/06; H01L 29/267

(52) U.S. Cl. CPC H01L 21/02694; H01L 21/02381; H01L 21/0245; H01L 21/02532; H01L 21/0259; H01L 29/0684; H01L 29/267

(57) ABSTRACT

There is described a method of manufacturing a semiconductor heterostructure. The method generally has: depositing an epitaxial layer of a first material atop a crystalline substrate, the crystalline substrate having a porous layer of a second material, the porous layer having a pore density above a pore density threshold, the second material different from the first material, heating the semiconductor heterostructure above a temperature threshold, said depositing and said heating diffusing atoms of the first material across the crystalline substrate and into the porous layer, the atoms of the first material at least partially filling voids of the porous layer thereby relieving strain existing between the first material of the epitaxial layer and the second material of the porous layer.

### FIELD

The improvements relate to semiconductor substrates and more particularly to semiconductor heterostructures.

### BACKGROUND

Semiconductor heterostructures are semiconductor structures in which chemical composition changes with position. An example of such semiconductor heterostructure is the silicon-germanium (Si—Ge) substrate. Although Si—Ge substrates are foreseen as an enabling technological brick to many technologies including light detection and ranging (LIDAR) systems, solar cells, lasers, to name a few examples, epitaxial growth of germanium on silicon substrates still faces significant challenges, especially in applications where surface quality is of importance. There thus remains room for improvement.

### SUMMARY

The aforementioned growth challenges generally stem from dissimilarities between lattice and thermal expansion constants of silicon and of germanium, and can be found in any other type of semiconductor heterostructures where two or more different materials share one or more interfaces. It was found that the method of manufacturing a semiconductor heterostructure described herein can at least partially alleviate the above-mentioned challenges and/or reach lower dislocation densities. As such, the method proposed herein can allow direct growth of materials in parametric mismatch while generating none or few dislocations or structural defects within the semiconductor heterostructure. The proposed method can also reduce the dissociation between epitaxial layers and prevent nucleation at dislocations. Accordingly, the semiconductor heterostructure manufactured using the method described herein can be used as a semiconductor substrate suitable for state-of-the-art applications as it can exhibit higher surface quality and a surface defect density lower than the dislocation density of 10⁶ cm⁻² generally associated to conventional Si—Ge substrates.

In accordance with a first aspect of the present disclosure, there is provided a method of manufacturing a semiconductor heterostructure, the method comprising: depositing an epitaxial layer of a first material atop a crystalline substrate, the crystalline substrate having a porous layer of a second material, the porous layer having a pore density above a pore density threshold, the second material different from the first material; heating the semiconductor heterostructure above a temperature threshold; and said depositing and said heating diffusing atoms of the first material across the crystalline substrate and into the porous layer, the atoms of the first material at least partially filling voids of the porous layer thereby relieving strain existing between the first material of the epitaxial layer and the second material of the porous layer.

Further in accordance with the first aspect of the present disclosure, said filling can for example include forming a strain relieving alloy with the second material of the porous layer of the crystalline substrate.

Still further in accordance with the first aspect of the present disclosure, the temperature threshold can for example range between about 50° C. and about 1400° C.

Still further in accordance with the first aspect of the present disclosure, the pore density can for example range between about 15% and 90%, the pore density defined as a volume of void over a volume of the porous layer.

Still further in accordance with the first aspect of the present disclosure, said heating can for instance be performed simultaneously to said depositing.

Still further in accordance with the first aspect of the present disclosure, said depositing is for example performed during a first period of time, and said heating is performed during a second period of time subsequent to the first period of time.

Still further in accordance with the first aspect of the present disclosure, said porous layer can for example include a plurality of microstructures distributed within the porous layer.

Still further in accordance with the first aspect of the present disclosure, said plurality of microstructures can for example be provided in the form of a plurality of micropillars extending at least partially perpendicularly to a plane of the crystalline substrate.

Still further in accordance with the first aspect of the present disclosure, the crystalline substrate can for example include a semiconductor material of one of a group IV element, a group III-V element, a group II-VI element, and a group III-N element, the first material can for example be a semiconductor material of one of a group IV element, a group III-V element, a group II-VI element, and a group III-N element, and the second material can for example be a semiconductor material of one of a group IV element, group III-V element, a group II-VI element, and a group III-N element.

Still further in accordance with the first aspect of the present disclosure, the crystalline substrate can for example be silicon-based, the first material can for example be germanium-based and the second material can for example be silicon-based.

Still further in accordance with the first aspect of the present disclosure, the method can for example further include, prior to said depositing, deoxidizing the crystalline substrate, said deoxidizing including chemically deoxidizing the crystalline substrate using a solution having hydrofluoric acid and ethanol.

Still further in accordance with the first aspect of the present disclosure, the method can for example further comprise, prior to said depositing, covering the crystalline substrate with a graphene layer, said covering being performed at a temperature ranging between about 300° C. and about 1000° C.

In accordance with a second aspect of the present disclosure, there is provided a semiconductor heterostructure comprising: an epitaxial layer of a first material received atop a crystalline substrate, the crystalline substrate having a porous layer of a second material, the porous layer having a pore density above a pore density threshold, the second material different from the first material, voids of the porous layer being at least partially filled with atoms of the first material thereby relieving strain existing between the first material of the epitaxial layer and the second material of the porous layer.

Further in accordance with the second aspect of the present disclosure, the porous layer can for example include a strain relieving alloy formed with the second material and the first material.

Still further in accordance with the second aspect of the present disclosure, the pore density can for example range between about 15% and 90%, the pore density defined as a volume of void over a volume of the porous layer.

Still further in accordance with the second aspect of the present disclosure, said porous layer can for example include a plurality of microstructures distributed within the porous layer.

Still further in accordance with the second aspect of the present disclosure, said plurality of microstructures can for example be provided in the form of a plurality of micropillars extending at least partially perpendicularly to a plane of the crystalline substrate.

Still further in accordance with the second aspect of the present disclosure, the semiconductor heterostructure can for example further comprise a buffer layer of a semiconductor material sandwiched between the crystalline substrate and the epitaxial layer.

Still further in accordance with the second aspect of the present disclosure, the crystalline substrate can for example further include a semiconductor material of one of a group IV element, a group III-V element, a group II-VI element, and a group III-N element, the first material can for example be a semiconductor material of one of a group IV element, a group III-V element, a group II-VI element, and a group III-N element, and the second material can for example be a semiconductor material of one of a group IV element, group III-V element, a group II-VI element, and a group III-N element.

Many further features and combinations thereof concerning the present improvements will appear to those skilled in the art following a reading of the instant disclosure.

### DESCRIPTION OF THE FIGURES

In the figures,

FIG. 1 is a schematic side view of an example of a semiconductor heterostructure, in accordance with one or more embodiments;

FIG. 2 is a flow chart of an example of manufacturing a semiconductor heterostructure, in accordance with one or more embodiments;

FIGS. 3A-D are cross-sectional views of scanning electron microscope (SEM) images of exemplary compliant substrates realized using patterned Si (001) porous substrates, where FIG. 3A shows a 10 μm tall deeply patterned silicon wafer formed using Bosch process; FIG. 3B shows anodized silicon pillars formed using an ethanol electrolyte;

FIG. 3C shows 2 μm tall self-limited Ge microcrystals grown at 500° C. by chemical beam epitaxy using a Ge KCell at 1250° C. on SiP; FIG. 3D shows 2 μm tall Self-limited Ge microcrystals grown at 500° C. by chemical beam epitaxy using a Ge KCell at 1250° C. PSiP (70%), in accordance with one or more embodiments;

FIG. 4A is a top view of a SEM image of an example Ge/SiP reference substrate; FIG. 4B is a top view of a SEM image of defect-free germanium grown on a porous silicon pillar (PSiP); FIG. 4C is a low magnification bright field (BF) transmission electron microscope (TEM) image of the Ge/SiP reference substrate of FIG. 4A; FIG. 4D is a low magnification BF-TEM image of the PSiP of FIG. 4B; FIG. 4E is a high resolution atomic resolution scanning transmission electron microscopy (STEM) image of the Ge/Si interface of FIG. 4C showing threading dislocations and misfits; and FIG. 4F is a high-resolution STEM image of the Ge/PSIP interface of FIG. 4D, in accordance with one or more embodiments;

FIG. 5A is a magnification BF-TEM image of an example of a Ge/SiP reference sample; FIG. 5B is a high-resolution TEM image of a Ge/SiP interface of the Ge/SiP reference sample of FIG. 5A showing misfit dislocation network; FIG. 5C is a low magnification BF-TEM image of several porous silicon pillars (PSiP) substrates with defect-free Ge crystals, FIG. 5D is an enlarged view of a porous structure of the PSiP substrate of FIG. 5C; FIG. 5E is a selected area electron diffraction (SAED) pattern image of the relaxed and monocrystalline Ge crystal on the porous structure of FIG. 5C, and FIG. 5F is a SAED pattern of the porous silicon;

FIG. 6A is an energy dispersive x-ray (EDX) mapping of exemplary porous pillars PSiP (70%) on a TEM lamella, FIG. 6B is a complete EDX mapping of an example interface Ge/PSiP; FIG. 6C is an EDX element maps for Ge elements; FIG. 6D is an EDX element maps for Si elements;

FIG. 7A is an EDX mapping showing Ge grow on PSiP (70%), FIG. 7B is a graph showing Ge concentration over the Si pillar;

FIG. 8A is a graph showing coupled scans ω-2θ of the Ge/SiP around the Si (004);

FIG. 8B is a graph showing coupled scans ω-2θ of the Ge/PSiP (70%) around the (224); FIGS. 8C-8F are reciprocal space mappings of the respective heterostructures around the symmetric Si (004) and asymmetric Si (224) reflections;

FIG. 9 includes coupled scans ω-2θ and reciprocal space mappings of the Ge/PSiP heterostructures performed around the Si (004) and (224) reflections;

FIG. 10A includes a 2D strain and rotation maps of Ge/Si pillars reference sample;

FIG. 10B includes a 2D strain and rotation maps of Ge/PSiP (70%), with purple box region as the arbitrary zero deformation;

FIG. 11 includes 2D strain and rotation maps of the Ge/Si pillars reference sample, with purple box region as the arbitrary zero deformation and horizontal and vertical lines are artefacts from the scanning unit;

FIG. 12 includes 2D strain and rotation maps of the interface Ge/Si pillars reference sample, with purple box region as the arbitrary zero deformation, and horizontal and vertical lines are artefacts from the scanning unit;

FIG. 13 includes 2D strain and rotation maps of the porous structure, with germanium region as the arbitrary zero deformation, and horizontal and vertical lines are artefacts from the scanning uni;

FIG. 14. includes 2D strain and rotation maps of Ge/PSiP (70%) interface, with germanium region as the arbitrary zero deformation, and horizontal and vertical lines are artefacts from the scanning unit;

FIG. 15A is a cross-sectional SEM image of exemplary porous silicon pillars PSiP (40%); FIG. 15B is a high-magnification SEM image of the mesoporous pillar structure of FIG. 15A; FIG. 15C is a cross-sectional SEM image of exemplary porous silicon pillars PSiP (50%); FIG. 15D is a high-magnification SEM image of the mesoporous pillar structure of FIG. 15C; FIG. 15E is a cross-sectional SEM image of exemplary porous silicon pillars PSiP (70%); FIG. 15D is a high-magnification SEM image of the mesoporous pillar structure of FIG. 15E;

FIG. 16A is a top SEM image of Ge/SiP; FIG. 16B is a top SEM image of Ge/PSiP (50%); FIG. 16C is a top SEM image of Ge/PSiP (70%), after Etch-Pit method;

FIG. 18A is a cross-sectional SEM image of Ge microcrystals grown on porous silicon pillars with PSiP (40%); FIG. 18B is a cross-sectional SEM images of reorganized porous silicon pillars after Ge growth for the porous silicon pillars of FIG. 18A; FIG. 18C is a cross-sectional SEM image of Ge microcrystals grown on porous silicon pillars with PSiP (50%); FIG. 18D is a cross-sectional SEM images of reorganized porous silicon pillars after Ge growth for the porous silicon pillars of FIG. 18C; and FIG. 18E is a cross-sectional SEM image of Ge microcrystals grown on porous silicon pillars with PSiP (70%); FIG. 18F is a cross-sectional SEM images of reorganized porous silicon pillars after Ge growth for the porous silicon pillars of FIG. 18E.

### DETAILED DESCRIPTION

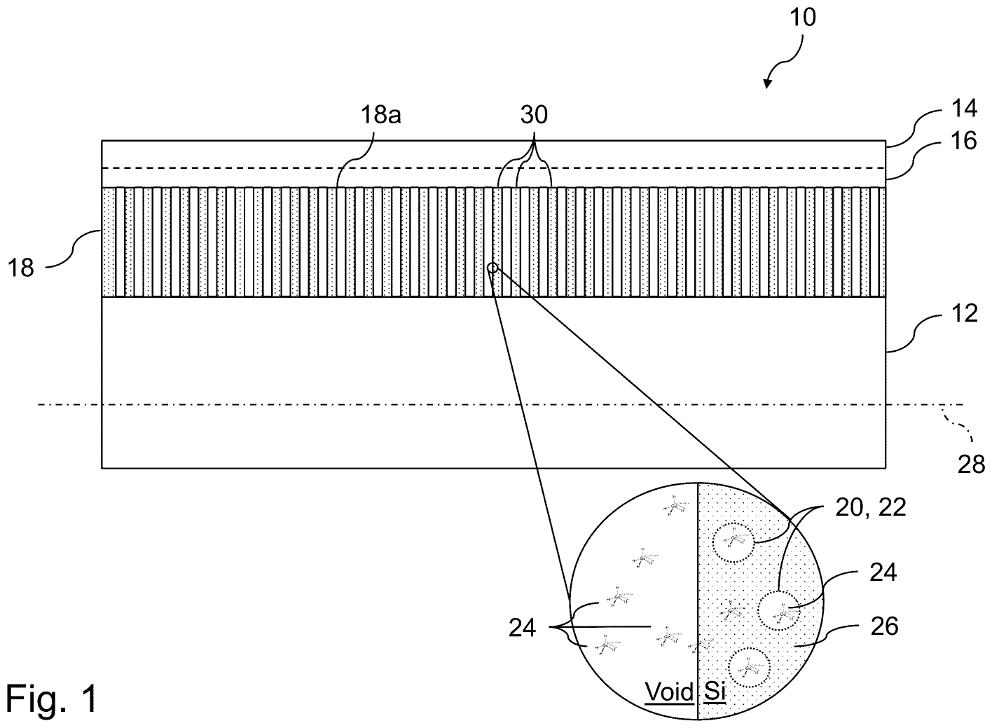

FIG. 1 shows an example of a semiconductor heterostructure 10, in accordance with an embodiment. The semiconductor heterostructure 10 can be used as a substrate for state-of-the-art applications including, but not limited to, LIDAR systems, solar cells, lasers and the like. As shown, the semiconductor heterostructure 10 has a crystalline substrate 12 and an epitaxial layer 14 of a first material received atop the crystalline substrate 12. In this example, the crystalline substrate is silicon. However, the crystalline substrate can include any semiconductor material of the group IV, the group III-V, the group II-VI, or the group Ill-N. In some embodiments, the semiconductor material of the crystalline substrate corresponds to the first material. However, in some other embodiments, the first material of the porous layer 18 can differ from the semiconductor material of the crystalline substrate.

In some embodiments, the semiconductor heterostructure 10 has a buffer layer 16 which is sandwiched between the crystalline substrate 12 and the epitaxial layer 14. In some embodiments, the buffer layer 16 includes a material corresponding to the first material. In some other embodiments, the buffer layer 16 and the epitaxial layer 14 are made of dissimilar materials. The buffer layer 16 is only optional as it can be omitted in some other embodiments. As depicted, the crystalline substrate 12 has a porous layer 18 of a second material. In some embodiments, the porous layer 18 has an exposed surface 18a which is covered by the buffer layer 16, if any, or the epitaxial layer 14 via a material deposition step, for instance.

As illustrated, the porous layer 18 has pores 20 distributed within the porous layer 18. Accordingly, the porous layer 18 has a pore density dₚₒᵣₑₛ above a pore density threshold d_{pores,threshold}, dₚₒᵣₑₛ>d_{pores,threshold}. In embodiments where the pore density is defined as a collective volume of void over a volume of the porous layer 18, the pore density ranges between about 15% and 90%. In some embodiments, the pore density is of about 70% or above. The pores 20 define voids 22 which have a dimension of at least 5 nm or greater, depending on the embodiments. The voids 22 can have any suitable type of geometries including, but not limited to, spherical, ellipsoidal, cubic and the like. Although the voids 22 are shown to be spherical in FIG. 1, the voids 22 can be elongated or arbitrarily shaped.

It is noted that due to the nature of semiconductor heterostructures which is to combine different materials, the first material is different from the second material. For instance, in this embodiment, the first material is germanium whereas the second material is silicon. Other material combinations can be used in some other embodiments. In fact, the first material can include any semiconductor material of the group IV, the group III-V, the group II-VI, or the group III-N. The second material can include any semiconductor material of the group IV, the group III-V, the group II-VI, or the group III-N, as long as it is different from the first material.

As shown, the voids 22 of the porous layer 18 are at least partially filled with atoms 24 of the first material, as they diffused therein during a step of depositing the epitaxial layer 14 atop the crystalline substrate 12. It was found that the presence of the atoms 24 of the first material in the voids 22 of the porous layer 18 tends to relieve strain existing between the first material of the epitaxial layer 14 and the second material of the porous layer 18. In some embodiments, the atoms 24 of the first material not only fill the voids 22 of the porous layer 18 but also form a strain relieving alloy 26 with the second material. As discussed in greater details below, the process of forming the strain relieving alloy 26 can depend on the combination of the materials used for the first and second materials, and also on the temperature at which the semiconductor heterostructure 10 is heated, and for how long. In some embodiments, the first and second materials are not compatible to form a strain relieving alloy. However, even in these embodiments, the presence of the atoms 22 of the first material within the pores 20 can nonetheless help in relieving the strain occurring within the semiconductor heterostructure 10.

In addition to the pores 20 of the porous layer 18, the porous layer 18 can have microstructures 30 distributed within the porous layer 18. In these embodiments, the microstructures 30 can be provided in the form of micropillars, microwires, or any other suitable type of geometry or shape. In embodiments where the microstructures are micropillars, the micropillars can have a square cross-section, a height of about 10 microns, an interpillar spacing of about 2 microns, and a width of about 2 microns. The geometry, shape and dimensions of the microstructures 30 can vary from one embodiment to another, and they can have an impact on the mechanical properties of the semiconductor heterostructure. As shown, the microstructures 30 can extend at least partially perpendicularly to a plane 28 of the crystalline substrate 12. However, the microstructures 30 do not necessarily extend perpendicularly to the plane 28 in other embodiments. The microstructures 30 can be uniformly, randomly or otherwise arbitrarily distributed within the porous layer 18. The microstructures 30 are only optional and can be omitted in some circumstances. In the embodiments where the microstructures 30 are omitted, the pores 20 and voids 22 can be uniformly, randomly or otherwise arbitrarily distributed within the porous layer 18.

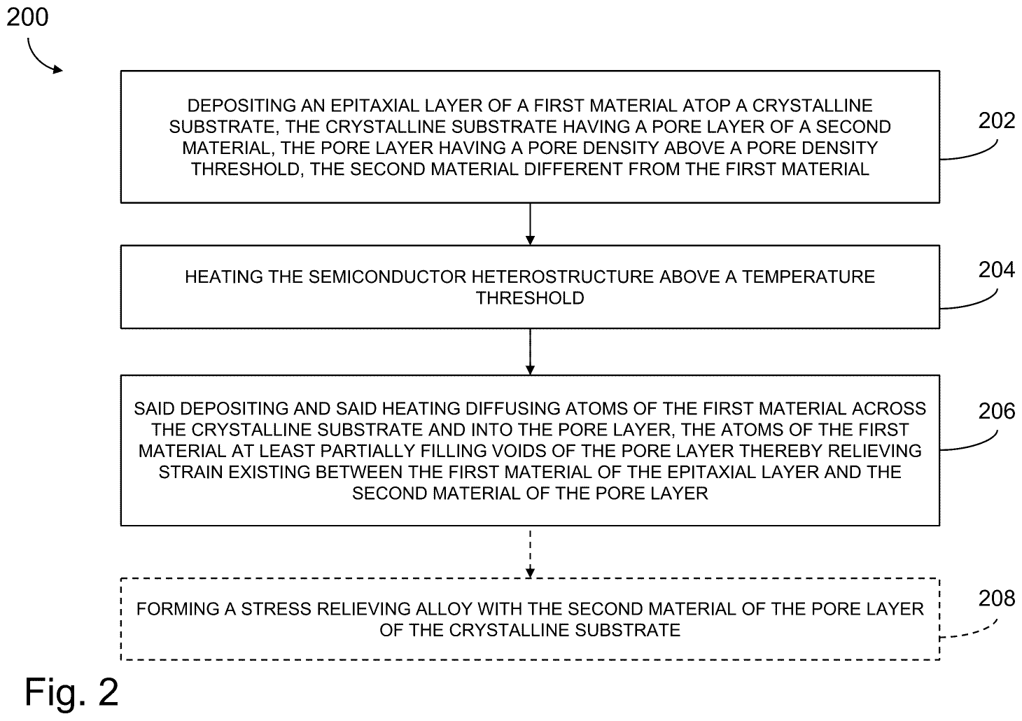

FIG. 2 shows an example of a method 200 of manufacturing a semiconductor heterostructure such as the semiconductor heterostructure 10 described with reference to FIG. 1.

At step 202, an epitaxial layer of a first material is deposited atop a crystalline substrate. The crystalline substrate has a porous layer of a second material which is different from the first material. In some embodiments, the crystalline substrate and the second material are silicon-based whereas the first material is germanium-based. However, as mentioned above, other material combinations are also possible in some other embodiments. The porous layer has a pore density above a pore density threshold. In some embodiments, the pore density ranges between about 15% and 90%. The pore density can be defined as a volume of void over a volume of the porous layer.

In some embodiments, the method 200 has a step of forming the porous layer within the crystalline substrate prior to the step 202 of depositing. In these embodiments, the porous layer can be made using electrochemical etching methods. However, in some other embodiments, the porous layer can be formed using different methods. The crystalline substrate can be purchased with the porous layer already formed therein.

At step 204, the semiconductor heterostructure is heated above a temperature threshold. It is noted that the temperature threshold depends on the materials used as the first material and the second material. For instance, in some embodiments, the temperature threshold can range between about 50° C. and about 1400° C. Indeed, for some material combinations, the step 204 of heating requires so little heating that only a few degrees Celsius above ambient temperature is satisfactory. However, some material combinations, temperatures ranging between 400° C. and 600° C. For instance, and for exemplary purposes only, the temperature threshold can range between 20° and 600° C. when the first material is germanium, the temperature threshold can range between 10° and 400° C. when the first material is germanium-tin (GeSn), the temperature threshold can range between 15° and 450° C. when the first material is silicon-germanium-tin (SiGeSn), the temperature threshold can range between 15° and 300° C. when the first material is silicon-tin (SiSn), the temperature threshold can range between 90° and 1300° C. when the first material is silicon carbide (SiC), the temperature threshold can range between 50° and 1300° C. for gallium nitride (GaN) or GaN-based materials, the temperature threshold can range between 50° and 1300° C. when the first material is aluminum nitride (AlN), the temperature threshold can range between 20° and 650° C. when the first material is indium phosphide (InP) or InP-based materials, the temperature threshold can range between 35° and 800° C. when the material is gallium arsenide (GaAs) or GaAs-based materials.

At step 206, the steps 202 and 204 cause diffusion of atoms of the first material across the crystalline substrate and into the porous layer. As discussed above, the atoms of the first material at least partially fill voids of the porous layer thereby relieving strain existing between the first material of the epitaxial layer and the second material of the porous layer. In some situations, especially when the first and second materials can chemically form a metal alloy, the step 206 includes a step 208 of forming a strain relieving alloy between the second material and the atoms of the first material which diffuse across and into the porous layer. It is understood that the diffusion of the atoms of the first material is gradual. Accordingly, the porous layer can have a gradient of first material extending within the porous layer. In some embodiments, more atoms of the first material are present proximate the top surface of the porous layer than at a bottom surface thereof.

It is noted that the rate of diffusion of the atoms of the first materials across and into the porous layer can depend on the thickness of the buffer layer, if any, on the rate of deposition of the first material and/or on the temperature threshold. The thinner the buffer layer, the greater the rate of diffusion; the greater the rate of deposition of the first material, the greater the rate of diffusion; and the greater the temperature, the greater the rate of diffusion. In some embodiments, the rate of diffusion is controlled to avoid having a too large amount of in-transit, diffusing atoms, which can in turn result in clogging if the diffusing atoms can find no clear path to the pores.

It is encompassed that, in some embodiments, the step 202 of depositing and the step 204 of heating are performed simultaneously. In these embodiments, the semiconductor heterostructure is heated, either wholly or locally, while the first material is deposited atop the buffer layer, if any, or the crystalline substrate. In some other embodiments, the step 202 of depositing is performed during a first period of time, and the step 204 of heating is performed during a second period of time subsequent to the first period of time. In some embodiments, the second period of time immediately follows the first period of time. In some other embodiments, the first and second periods of time can be temporally spaced apart from one another or temporally overlapping with one another.

In some embodiments, a first epitaxial layer of the first material is first deposited atop the crystalline substrate after which the first epitaxial layer is heated above the temperature threshold for a given period of time in order to let a first phase of diffusion occur. In these embodiments, a second epitaxial layer of the first material can be deposited atop the first epitaxial layer after which the first and second epitaxial layers can be heated above the same or another temperature threshold for a same or another period of time, and so forth, depending on the embodiment. In these embodiments, the first epitaxial layer, the second epitaxial layer and any other epitaxial layers deposited thereon can ultimately form a single epitaxial layer of the first material. In some embodiments, such incremental depositing and heating steps can be performed to tune or otherwise optimize the diffusion of the atoms of the first material across and into the porous layer.

In some embodiments, the method 200 has a step of deoxidizing the crystalline substrate prior to the step 202 of depositing. In these embodiments, the step of deoxidizing can include a step of chemically deoxidizing the crystalline substrate using a solution containing an acid such as a solution having hydrofluoric acid and ethanol. The step of deoxidizing can be especially convenient to remove an oxidized layer atop the crystalline substrate, which can occur when the crystalline substrate is subjected to ambient air or environment. In some embodiments, one or more thermal annealing steps are performed to the crystalline substrate before and/or after the step of deoxidizing.

In some embodiments, the method 200 can include a step of covering the crystalline substrate with a graphene layer prior to the step 202 of depositing. In these embodiments, the step of covering can include applying the graphene layer atop the crystalline substrate while heating the crystalline substrate at a temperature ranging between about 300° C. and 1000° C., and most preferably at about 600° C. The graphene source can originate from methane or acetylene, to name a few examples. In these embodiments, the graphene layer can act as a buffer layer. Accordingly, the epitaxial layer is deposited atop the crystalline substrate via the graphene layer. In other words, the epitaxial layer is not deposited directly atop the crystalline substrate but indirectly thereto via the graphene layer. In some embodiments, the graphene layer can be used to receive a greater variety of materials including, but not limited to, GaN, AlN, SiC and the like.

### Example—Defect Free Strain Relaxation of Microcrystals on Mesoporous Patterned Silicon

In this example, there is presented a perfectly compliant substrate that can allow the monolithic integration of high-quality semiconductor materials such as Ge and III-V on Silicon (Si) substrate, enabling novel functionalities on the well-established low-cost Si technology platform. More specifically, this example demonstrates a compliant Si substrate allowing defect-free epitaxial growth of lattice mismatched materials. The proposed method is based on the deep patterning of the Si substrate to form micrometer-scale pillars and subsequent electrochemical porosification. The investigation of the epitaxial Ge crystalline quality by X-ray diffraction, transmission electron microscopy and etch-pits counting demonstrates the full elastic relaxation of defect-free microcrystals. The achievement of dislocation free heteroepitaxy relies on the interplay between elastic deformation of the porous micropillars, set under strain by the lattice mismatch between Ge and Si, and on the diffusion of Ge into the mesoporous patterned substrate attenuating the mismatch strain at the Ge/Si interface.

Over the last decades semiconductor technology has become essential for automotive, biomedical, sensing, and environmental monitoring applications. Devices such as light-emitting diodes, photodetectors, lasers and solar cell are ubiquitous in consumer, industrial, and scientific appliances. Those complex devices rely on epitaxial growth ensuring high crystalline quality, abrupt interface, accurate alloy composition and doping level. However, crystal growth remains sensitive to the difference in lattice parameter between the epilayer and the substrate as well as the difference in thermal expansion coefficients. Depending on the lattice mismatch, strained epitaxial material fitting the substrate structure, can be grown pseudomorphically ensuring coherent strain distribution up to a critical thickness when plastic relaxation and defect creation appear as an elastic energy relaxation mechanism. Beyond this critical thickness, the epitaxial layer will release the strain energy giving rise to defect nucleation such as misfit and threading dislocations, which are detrimental to device performance and must therefore be avoided or at least minimized. In heteroepitaxy, the difference in lattice parameter between the substrate and the epitaxial layer require some kind of mitigation in order to reach application quality material. Without such mitigation, the variety of suitable substrates that can ensure high quality epitaxy is limited compared to the diversity of materials and alloys required for the synthesis of high performances devices.

To tackle this problem, different attempts involving the use of standard substrates have been proposed over the past decades to reduce the threading dislocation density (TDD), which is the main source of detrimental effects on the epilayer. Metamorphic growth involving several microns thick buffer layer either by compositional grading or several high temperature annealing cycles, has particularly achieved attractive results, and has succeeded in decreasing the TDD down to a threshold of 106 TD/cm². Other alternative methods consider patterned substrates as a mean to reduce the defects. Accordingly, three-dimensional (3D) growth of Ge and/or SiGe on deeply patterned Si substrate has been found efficient for TDs elimination by allowing them to propagate towards the free surface of the pattern features sidewalls. However, those methods still require thick buffer layer with relatively high defect density, mostly around 106 TD/cm², associated with well pronounced misfit dislocations (MF) network, which precludes the synthesis of devices demanding very thin active layers close to the interface. Recent study has shown that nanovoid-based virtual substrate (NVS) can be used to decrease the TDD down to 104 TD/cm², but still limited to Ge/Si system. Moreover, metamorphic growth implies long growth times to create the thick transition layer, effectively increasing the time and cost of the desired structure.

Back in the nineties, researchers proposed a method based on a theoretical model called “compliant substrate”, which is supposed to create the conditions for defect-free heteroepitaxy. This method is based in the idea of reducing the substrate's effective thickness, so that the compliant substrate accommodates a large part of the strain, increasing the critical thickness of the epilayer and allowing a pseudomorphic growth of thicker defect-free layer. Several studies have been performed to experimentally demonstrate this theory, for instance the development of free-standing nano-membranes and ion-implantation. This later can be used to reduce the difference in lattice parameter, while thin membrane allows the epilayer to relax to its natural lattice constant. The membrane can be then transferred to a host substrate. Despite promising results shown by these methods, achieving an effective and practically useful compliant substrate remains a challenge. Indeed, the very thin nature of such membranes engenders handling difficulties during microfabrication and layer transfer processes regarding surface contamination and mechanical stability of the final device. Other methods have also been proposed in the literature to reach compliance, but still present limitations regarding their scalability.

Van Der Waals heteroepitaxy on graphene has recently generated increasing interest. With this method the strain is taken up by the graphene intermediate layer, since its deformation energy is lower than the one required to form a defect due to plastic relaxation. Since the Van der Waals's bonds are very weak, growth on graphene also presents benefits regarding easier layer transfers. However this method requires the graphene transfer, which is difficult to implement at industrial scale.

Porous silicon is a promising material to reach such a compliance. Indeed, its mechanical properties can be tuned depending on the porosity, leading to an elastic material with low Young's modulus while remaining crystalline. Several studies have been realized on the growth of GaAs, SiGe or Ge on mesoporous silicon. However, those studies did not highlight the compliant properties of standard porous silicon substrate. Only a slight improvement of crystalline quality has been noticed. Free-standing graphene mesoporous Si membrane has already been proposed as complaint substrate for the growth of GaN with high potentiality to accommodate the strain energy during epitaxy. Nevertheless, the effectiveness of conventional porous silicon as a suitable compliant substrate is limited by the reorganization of the porous structure during the epitaxial process involving high temperature, the lattice accommodation between the substrate and the epilayer or even by the brittleness of the porous silicon membrane.

In this example, we propose a fully compliant Si substrate as a practical way towards the long-standing goal of defect-free heteroepitaxy of lattice mismatched materials on the industry-standard silicon substrates. The proposed solution paves the way towards monolithic integration of wide range of optoelectronic devices with advanced applications and functionalities through band engineering on Si substrate. The method relies on the deep patterning of the Si substrate to form micrometer scale pillars and subsequent electrochemical porosification. Considering the Ge epitaxy on Si substrate as a case study, the tower morphology of the Si pillars allows full elastic relaxation of the thermal strain whereas, the porosification reduces the pillars Young's modulus allowing easy deformation to accommodate the lattice mismatch strain. The results demonstrate the full compliance of the silicon substrate revealing unprecedented dislocation-free Ge microcrystals regardless the deposited thickness. Our finding paves the way to achieve high quality germanium for active photonic devices on Si platform.

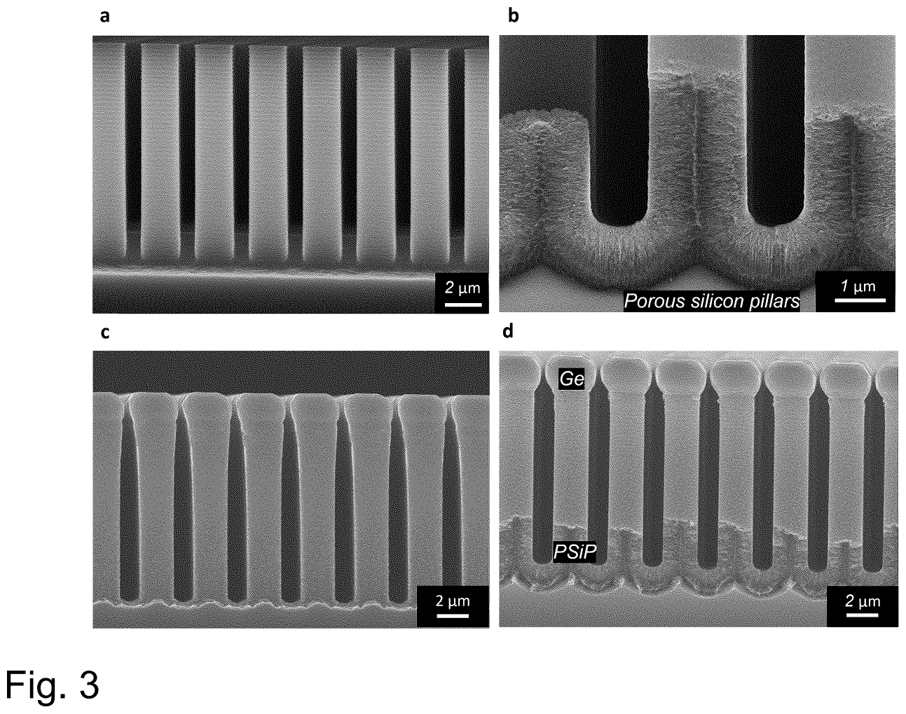

Typical cross section SEM micrograph of the compliant Si substrate is shown by FIG. 3. The substrate is formed by deep patterning and porosification.

SEM image of Bosch process deeply patterned p-type Si (001) wafers with ordered square-based 5×5 cm² arrays of Si pillars separated by 2 μm trenches used as substrates is shown by the FIG. 3a. The obtained Si pillars were anodized (FIG. 3b) in O-ring electrochemical cell with an electrolyte composed of HF (49%) and anhydrous ethanol to form mesoporous Si pillars with 70±5% porosity. A 200 nm thick Ge buffer layer has been first deposited at 200° C. prior to the growth of 2 μm thick Ge layers by Chemical Beam Epitaxy at 500° C. (TC) using a solid source Ge. The aim of the low temperature buffer layer is to close the pores, defining then a suitable flat surface and to minimise the Ge diffusion into the porous Si pillars. An identical growth procedure has been used to deposit Ge on a patterned substrate which did not underwent the porosification procedure. Due to the patterning of the substrate, 3-dimensional Ge microcrystals are obtained on both Si pillar (SiP) and porosified Si pillars (PSiP) (FIG. 3c,d). It has been previously shown that the growth of Ge at low deposition temperature enhances the vertical growth of Ge crystal on the Si pillars and, optimizing the deposition conditions it is possible to expel threading dislocations at the lateral sidewalls of the Ge microcrystal.

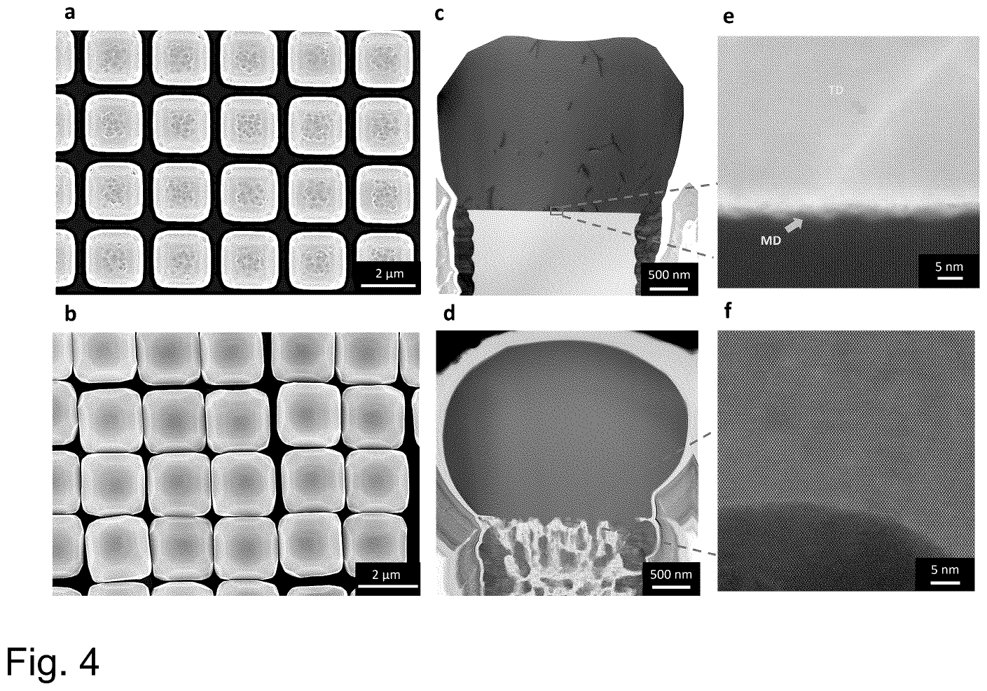

A full elastic strain accommodation should be accompanied by the absence of TDs. To validate this, etch-pit (EP) counting has been performed on both Ge epitaxial material deposited on SiP and PSiP. For this purpose, samples were immersed in a solution of two volumetric parts 49 wt % HF and 1 part 0.1 M K₂Cr₂O₇, where mixed and screw dislocations in the Ge material get selectively etched allowing their quantification by using plan view SEM observations. The average defect density has been extracted from different Ge/SiP and Ge/PSiP top-view SEM images. As shown by the FIG. 4a, relatively high TDD around 5.108 cm⁻² is found to reach the surface for Ge grown on SiP. Meanwhile, for Ge grown on PSiP, the surface appears completely free of pits implying that no TD dislocation reaches the surface (FIG. 4b). This result constitutes a first confirmation that the PSiP concept succeeds in accommodating the lattice mismatch strain. A tilt of the structure can be observed in FIG. 4b due to the bending of the high elastic pillars. These results highlight the potential scalability of our method.

To gain more insights on the structural properties of the Ge microcrystals, and more precisely the interface and in-depth distribution of the dislocations, TEM cross-sectional observation of Ge epitaxial material on SiP and on PSiP have been performed (FIG. 4c,d).

Indeed, as shown by SEM (FIG. 4a) and TEM (FIG. 4c) micrographs, the Ge grows on SiP with multiple facets due to the pillars tower morphology. Threading dislocations that are not parallel to the growth direction are expelled to the sidewall of the pillars. It has already been shown that it is possible to completely expel TDs from the top part of the microcrystal, however, this requires the combination of suitable growth conditions and pillar widths, together with a relatively large microcrystal thickness. As we can deduce from the TEM observations (FIG. 4c) of the reference sample, the Ge surface exhibits facets oriented towards the center of the structure. Since growth dislocation propagate in a perpendicular direction of the facets, those vertical dislocations can reach the surface. As expected, defects appear in Ge microcrystal on SiP due to lattice mismatch. However, in the case of Ge grown on the porous structure (FIG. 4d) in accordance with the method described herein, no threading nor misfit dislocations appeared in the Ge epitaxial material as can be appreciated from FIG. 4F.

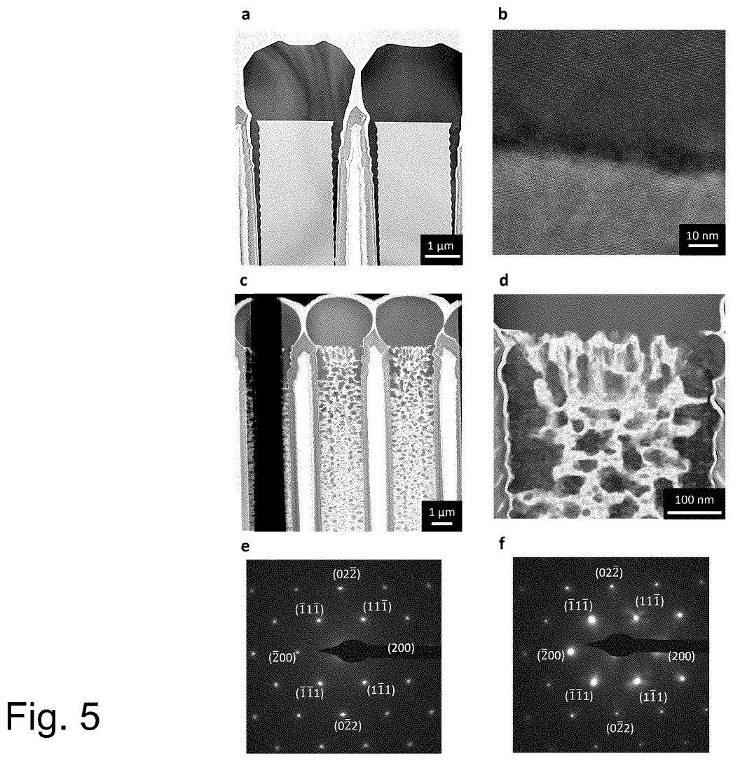

These widely sought properties can be exploited to achieve Ge based photonic and optoelectronic devices that require very thin thickness. This constitutes a direct proof of porous Si pillars properties being able to accommodate the mismatch strain. Selected area electron diffraction (SAED) images (FIG. 5e,f) highlight a monocrystalline Ge microcrystal, while the porous structure presents an enlargement of the dots and a deformation, which indicate a porous crystallites deformation. TEM observations were performed on several pillars for each Ge grow on SiP and PSiP substrates. The defects appeared in the reference sample with the dislocation misfit network, while Ge microcrystals grown on PSiP substrate remain defect-free. SAED patterns confirm the monocrystalline and relaxed Ge microcrystal obtained on PSiP. Moreover, the deformation of the dots in the SAED pattern related to the substrate shows the lattice accommodation of the porous template and SiGe compound.

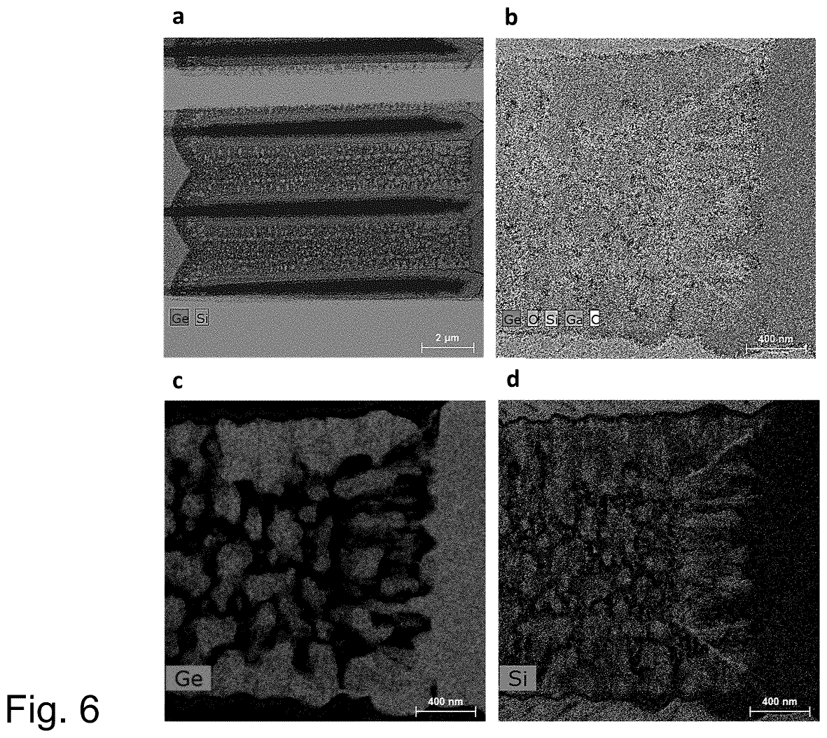

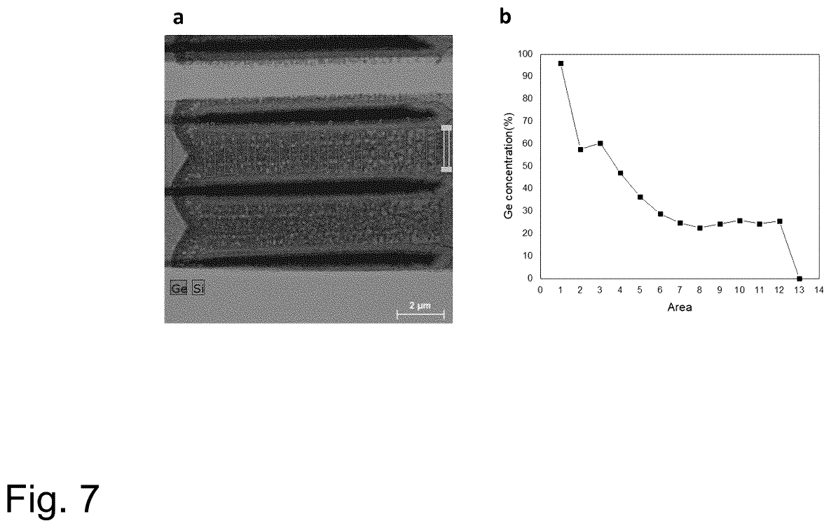

EDX observations in FIG. 6, revealed the penetration of Ge into the porous structure due to high specific surface. On the other hand, a graded interdiffusion of Ge and Si can be observed. As can be observed, the Ge diffused into the porous structure, which would induce a strain on Si. The deformation induced by this infiltration/diffusion of Ge leads to a lattice deformation of the mesoporous Si towards Ge lattice parameter and reduce the strain in this heterostructure. Due to the Ge diffusion length, the Ge concentration in the resulting SiGe graded structure, increase near the interface and the sidewalls (FIG. 7). This SiGe synthesis can also contribute to the dots deformation in SAED patterns.

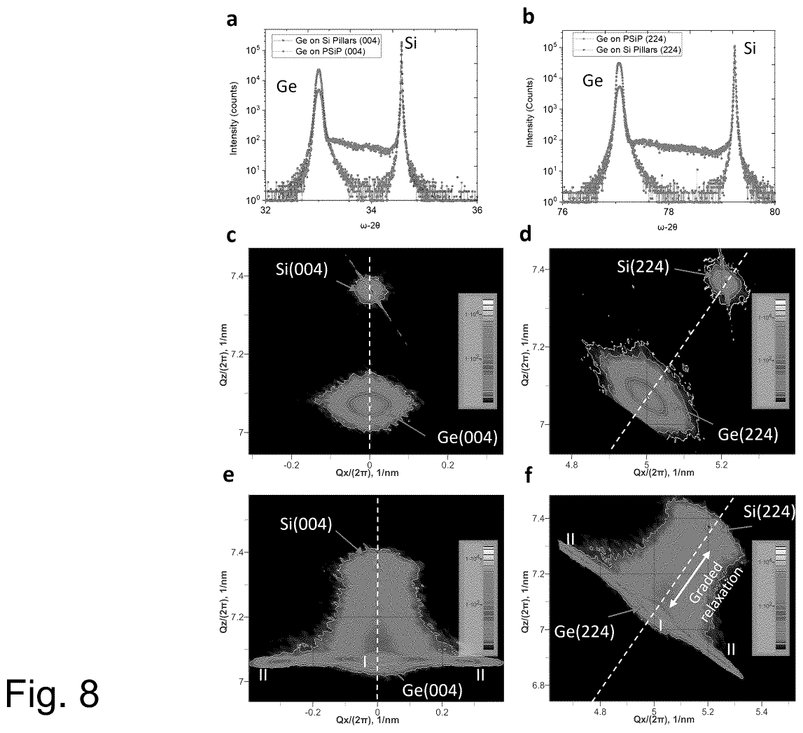

In order to assess the crystalline quality and residual strain, high resolution x-ray diffraction, coupled with reciprocal space mapping around the symmetrical Si (004) and asymmetrical Si (224) reflections for both heterostructures grown on SiP and PSiP (70%) substrates were performed, as shown in FIG. 8.

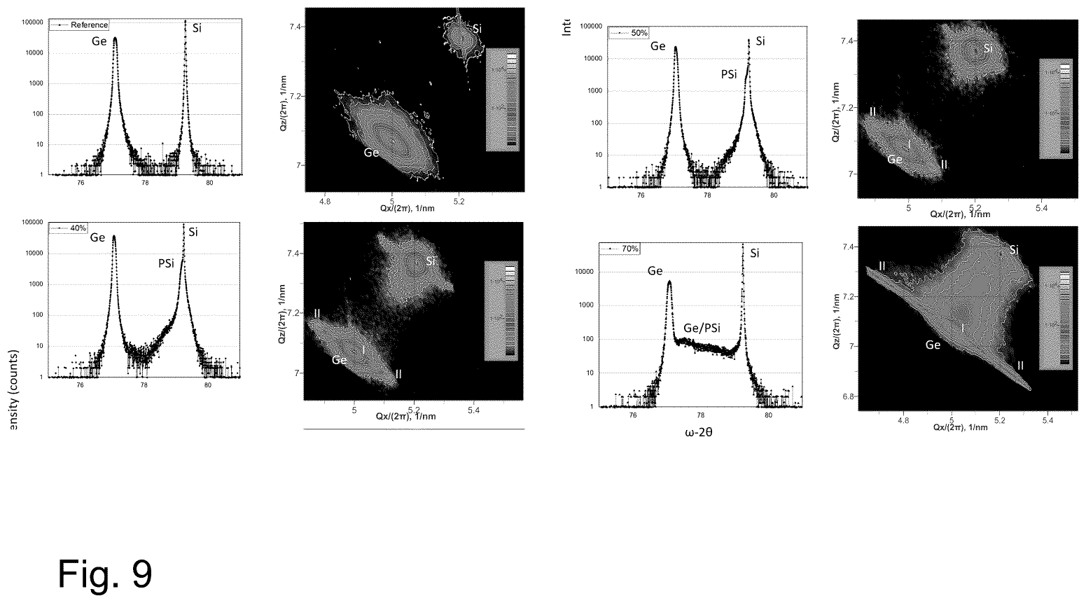

As can be observed on the coupled scans (FIG. 8a,b), the full width at half maximum (FWHM) of the Ge peak grown on the porous structure is narrower than the one obtained with the reference on SiP, which confirm the improvement of the crystalline quality using such compliant substrate. Additionally, in case of Ge growth on PSiP a plateau between Ge and Si arises. This phenomenon suggests a progressive accommodation of the lattice strain between both materials. Indeed, owing to the high porosity, the porous silicon pillars exhibit low Young's modulus allowing easy deformation to accommodate the lattice mismatch with the Ge microcrystals. Also, as it could be seen previously, the high amount of voids in the porous structure allows the infiltration of Ge as well as interdiffusion that lead to the formation of the Si1-xGex compound effectively reducing the lattice mismatch between the PSiP and the Ge microcrystal. The lattice deformation of the porous silicon favors the Ge diffusion. Nonetheless, the well-known growth of graded layer is not enough to annihilate the lattice strain within only a few micrometers. In the present case, both phenomena, the porous structure deformation, and the interdiffusion of Si and Ge mediated by the porous structure, coexist giving rise to the observed elastic strain accommodation. The graded accommodation occurs only when the porosity reaches 70% (FIG. 9) suggesting a threshold porosity that may vary depending on the epitaxial material. This highlight that the porosity constitutes a key parameter to accommodate the lattice mismatch strain.

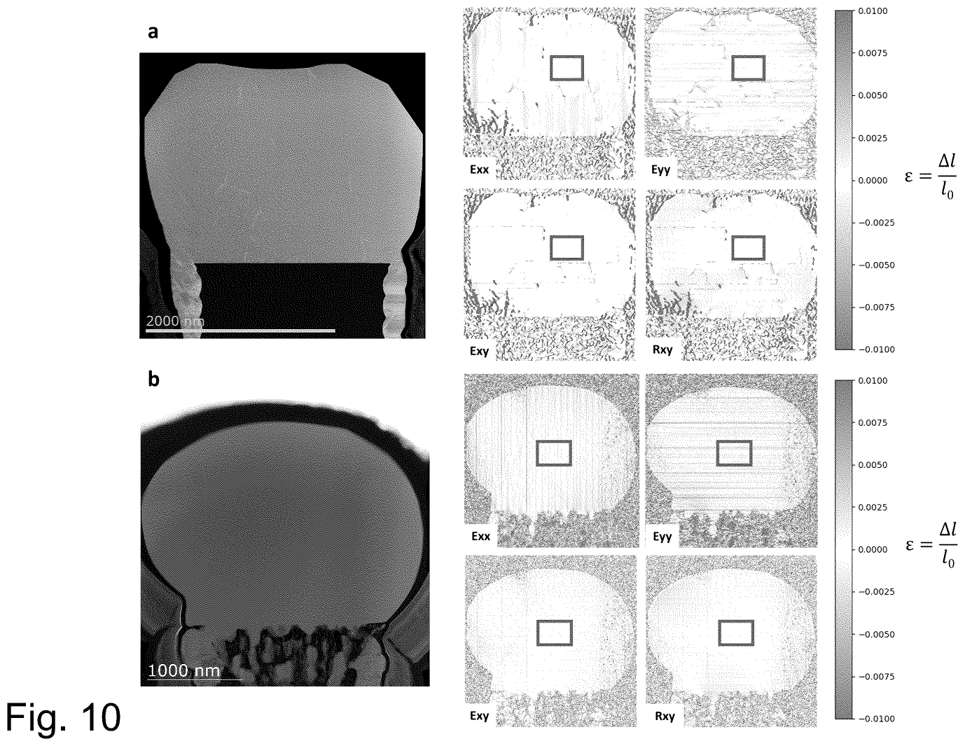

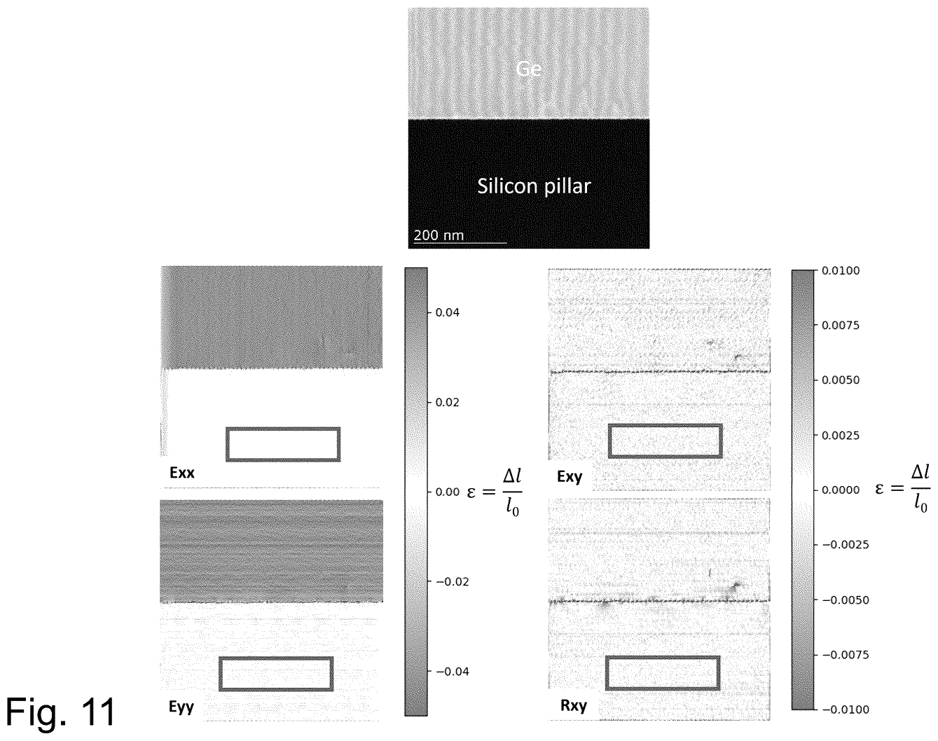

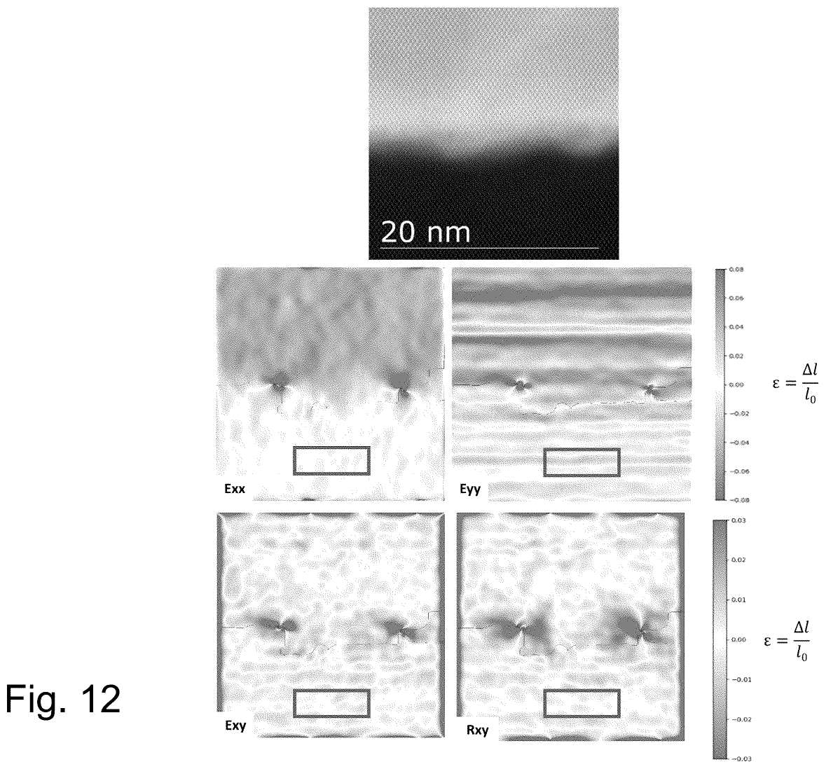

To clarify the compliant properties of such substrate, strain mapping using the STEM Moiré GPA method was performed. FIG. 10, describes the obtained results for Ge/SiP and Ge/PSiP (70%) respectively. Using the centre of the Ge microcrystal as the arbitrary zero deformation, the strain and rotation maps demonstrate that the relative deformation field is globally very low in the whole Ge region for both samples. As the lattice mismatch between Ge and Si is around 4.18%, significant strain relaxation is expected from the side of the Ge pillar if the Ge material is lattice matched to the Si underneath. The very low deformation field suggest that nearly no strain relaxation is observed from the side of structure. Therefore, the Ge regions in both the reference and the Ge/PSiP samples are nearly fully relaxed. For the reference sample, the strain between Ge and Si pillars from the atomic misfit is released at the interface between materials with a well define misfit dislocations network and threading dislocations in the Ge microcrystal (FIG. 11 and FIG. 12). For the Ge/PSiP sample, the Ge grows from Si₁₋ₓGeₓ template is able to reduce the relative atomic misfit and potentially allow the Ge mechanical constraints to be accommodated with a local elastic deformation.

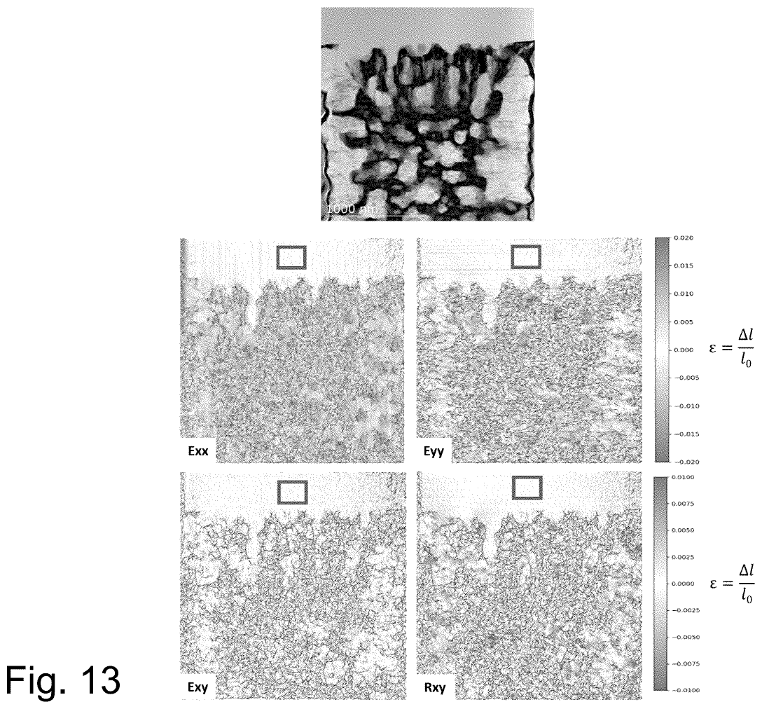

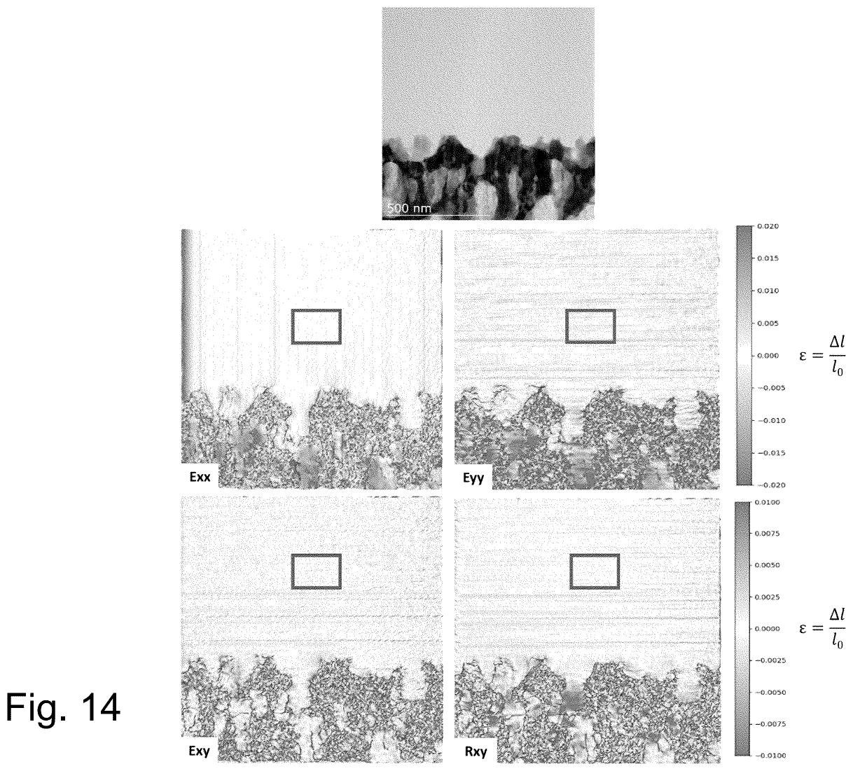

The germanium grown on PSiP presents a pronounced strain state located at the proximity of the Si1-xGex compound between the pores (FIG. 13 and FIG. 14). The material incorporated in the porous structure is also compressed in both in-plane and vertical directions compared to the Ge microcrystal and this would suggest that most of the Si₁₋ₓGeₓ material seems to be nearly fully relaxed. However, without knowing the composition at the precise location it is difficult to be conclusive on the strain state of those compounds. Variations of deformation are observed in the substrate which can be both related to the different alloy composition or a real elastic deformation. Accepting the limitation in the data interpretation, the STEM Moiré GPA strain mappings, with both XRD and the STEM EDX, results are in good agreement to confirm the strain accommodation due to the gradual Si1-xGex formation and the deformation of the porous substrate allowed by its elasticity. This strain accommodation leads to the formation of defect-free microcrystals, which can be easily turned into a two-dimensional layer suitable for device synthesis by increasing the deposited thickness.

We report the synthesis of a fully compliant substrate for the epitaxial growth of lattice mismatch material on silicon. Combining micro-patterning of silicon substrate and mesoporous crystalline structure allow full accommodation of both lattice and thermal strain. We have shown for the Ge/Si (001) heterostructure that the porosity allows a strain accommodation, through suppressing the nucleation of dislocations via porous crystallites deformation and SiGe compound formation within the mesoporous structure. TEM observations and etch-pit counting reveals the absence of any defects in Ge microcrystals grown on PSiP while Ge on SiP present high defect density. XRD characterizations confirm the improvement of Ge crystalline quality on porous medium, and the graded relaxation between materials. EDX highlight the penetration of the Ge in the porous structure and the SiGe formation, while strain mappings confirm the strain accommodation allowed by the compliant substrate.

The porous structure allows to avoid formation of any defect at the interface, which not only yields a high-quality material but also allow for more long-term reliability of future devices. Thus, this method allows the synthesis of devices requiring very low thickness and would decrease the cost and time associated to the growth process of metamorphic structures.

This study provides a proof of concept for the synthesis of effective compliant substrate for heteroepitaxy and the integration of lattice mismatch microcrystals on Si platform. The method used can provide similar defect-free system on large surface area and a practical template for microfabrication processes. We believe that such compliant template can be extended to the direct growth of various materials such as GaAs, InP and GaN. The pillar structure can naturally be tuned to maximize the yield of photonics devices.

The following paragraphs present information relating to the method of manufacture. For instance, the 400 μm thick Si(001) p-type (B) (0,01-0.02 Ohm·cm) substrates were patterned by deep reactive ion etching (DRIE) based on the Bosch process with high etch rate (few micrometers per minute) and good anisotropy. As a result, we obtain 2 μm*2 μm square pillars, 10 μm tall, separated by 1 μm gap.

Prior to porosification, patterned substrates were cleaned using ethanoic alcohol for 10 minutes follow by 5 minutes in isopropanol. To perform the etching of Si pillars, a custom-made electrochemical cell of Teflon was employed. The electrochemical cell consisted of a copper electrode as the backside wafer contact (isolated from the electrolyte), a platinum counter-electrode and the patterned substrate as the working electrode. Most of Porous Silicon Porous (PSiP) was obtained by classical bipolar electrochemical etching (CBEE) process. An anodization was carried out in an O-ring electrode with an HF:Ethanol (volume:volume) electrolyte. The substrate used was a one-side polished, B-doped, p-type (100) Si wafer. The 400 μm thick wafers were 5×5 cm² with a measured resistivity between 10 and 20 mΩ·cm. HF last process (5% diluted) pre-cleaning of Si pillars and PSIP substrates was performed to suppress native oxide (SiO2) formation, then blown dry with nitrogen and introduced into the loading chamber of the CBE reactor.

Ge growth was carried out in a VG Semicon VG90H CBE reactor. A thermocouple was used for growth temperature monitoring. Ge microcrystals were grown using a solid source of Ge with a KCell temperature kept constant at 1250° C. The base pressure in the load-locked growth chamber was below 1×10⁻⁶ Torr, whereas during growth the pressure was ˜8.4·10⁻⁶ Torr.

The morphology and thickness of the grown microcrystals and porous structure were characterized with a LEO 1530VP scanning electron microscope (SEM). Porosity was first determined using ImageJ software. Accurate determination of the porosity was determined using Fourier-transform infrared spectroscopy (FTIR). Spectrums were recorded with a Hyperion 2000 FTIR microscope using a Globar source, a KBr beam splitter and a MCT D316 detector.

The structural properties of the microcrystals were investigated by using Rigaku SmartLab system, equipped with a 2-bounces Ge (220) crystal monochromator on the incident beam. The high-resolution x-ray diffraction measurements, ω-2θ scans and reciprocal space maps (RSMs) were performed around the Si (004) symmetrical and (224) asymmetrical Si reflections with Cu Kα1 radiation.

The etch pit method was carried out using a mixture of 2 volumetric parts 49 wt. % HF and 1 part 0.1 M K₂Cr₂O₇. Etch pits were counted on the top surface by examining Top-view SEM images of different pillars.

Porous medium present different optical properties compared to the original bulk sample. Therefore, the incident infrared light on the mesoporous Si substrate will be reflected from two different interfaces: air/porous Si and porous Si/Si substrate. Considering these different interfaces, the transmitted and reflected radiations will result in a Fabry-Perot interference spectrum. This interference pattern obtained with the reflective measurement is used to determine the refractive index of the porous medium (n_{Porous}) with the equation (1):

$$\\ \begin{matrix}m {λ}_{max} = 2 {n}_{Porous} L , & ( 1 )\end{matrix}$$

where m is the order of the fringe, λₘₐₓ is the wavelength of the fringe maximum, L the thickness of the porous structure (determined using SEM observations) and 2n_{Porous} L is the effective optical thickness. Therefore, the linear equation can be used for each maximum peak:

$$\\ \begin{matrix}m = 2 {n}_{Porous} {}_{} L {}_{} ( \frac{1}{{λ}_{max}} ) + b . & ( 2 )\end{matrix}$$

The Bruggeman Effective Medium approximation (Equation 3) is well suited for determining the porosity of the mesoporous Si:

$$\\ \begin{matrix}( 1 - P ) \frac{( {n}_{Si}^{{}_{} 2} - {n}_{Porous}^{{}_{} 2} )}{( {n}_{Si}^{{}_{} 2} + 2 {n}_{Porous}^{{}_{} 2} )} + P \frac{( {n}_{Pore}^{{}_{} 2} - {n}_{Porous}^{{}_{} 2} )}{( {n}_{Pore}^{{}_{} 2} + 2 {n}_{Porous}^{{}_{} 2} )} = 0 , & ( 3 )\end{matrix}$$

where P is the porosity, nₛᵢ and n_{Pore} are the refractive indexes of Si bulk and the medium filling the pore (air) respectively.

The samples were prepared using a Zeiss NVision 40 Focused Ion Beam (FIB). The target locations were first coated with electron-beam-induced carbon deposition to protect the surface from being sputtered off by the ion beam and followed by ion-beam-induced deposition of tungsten for further protection throughout the FIB process. The target locations were extracted from the specimen and attached to copper FIB grids using a conventional FIB milling and lift-out procedure, with the exception that the extractions were significantly taller than a typical FIB lamella. The purpose was to capture the full height of the pillars and to leave enough substrate material remaining below the pillars to maintain a thick bottom frame for structural support.

Additionally, a support frame was utilized to split the thin window into two, which is intended to reduce the impact of warping when the window thicknesses are reduced towards TEM transparency. This method also enables the lamella to possess two different thicknesses to better optimize for a wider variety of characterization techniques. The thinning was performed with the ion beam voltage at 30 kV using milling lines of progressively smaller beam currents down to 40 pA. Final cleaning steps were performed with the ion beam voltage at 10 kV and 5 kV using a glancing angle raster box with the stage tilted 8 degrees below the tilt angle of the thinning step.

TEM/STEM observations were made on a Titan Themis 200 microscope (FEI/Thermo Fischer Scientific) equipped with a geometric aberration corrector on the probe. The observations were made at 200 kV with a probe current of about 50 pA and a half-angle of convergence of 17 mrad. HAADF-STEM images were acquired with a camera length of 110 mm (inner/outer collection angles were respectively 69 and 200 mrad). The microscope is also equipped with the “SuperX” EDS elemental analysis system with 4 windowless EDX detectors (detection angle θ.8 steradian).

The STEM imaging was performed on a FEI Titan Cubed 80-300 equipped with CEOS correctors on both the probe and image-forming lens systems operating at 200 keV. The STEM probe size, current and semi-convergence angle were approximately 100 μm, 80 pA, and 19.8 mrad respectively. The STEM acquisition conditions were set to obtain Z-contrast type STEM electron micrographs with inner/outer angles of the Fischione annular dark-field (ADF) detector of 50 and 200 mrad respectively. The strain characterization was performed using the STEM Moiré GPA method and processed using a homemade open-source python script available on a public repository.

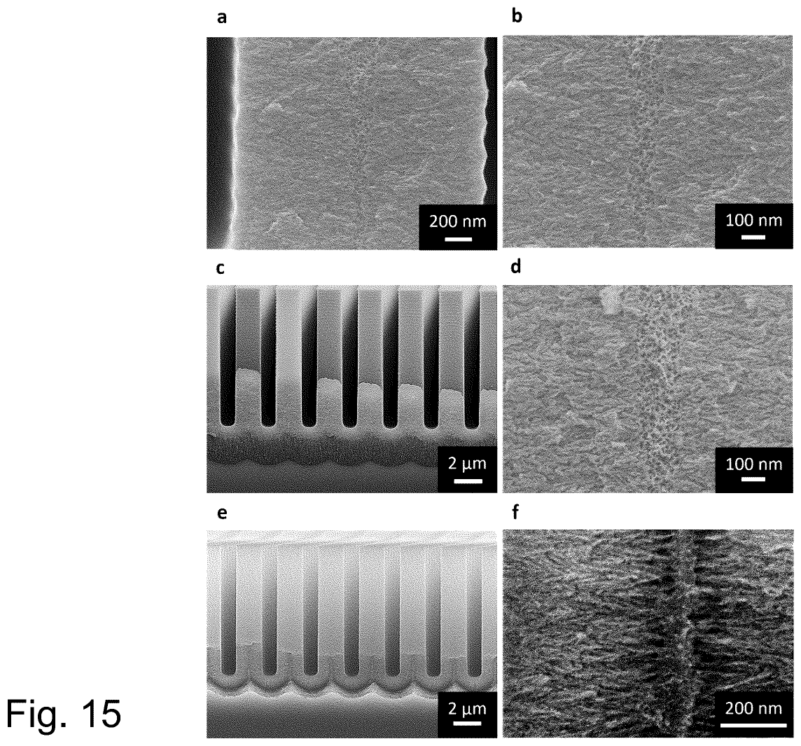

FIG. 15 show SEM images of Bosch process deeply patterned p-type Si (001) wafers (10-20 mOhm·cm) with ordered square-based 5×5 cm² arrays of Si pillars separated by 1 μm trenches used as substrates is shown by the FIG. 3a. The obtained Si pillars were anodized (FIG. 3b) in O-ring electrochemical cell with an electrolyte composed of 1:3 volume ratio of HF (49%) and anhydrous ethanol and a 50 mA/cm² current density to form a 2 μm thick mesoporous Si pillars with 70±5% porosity. The electrochemical etching of silicon pillars leads to the formation of a dendritic morphology perpendicular to each free surface exposed by the patterned substrate.

To understand the effect of porosity on lattice strain accommodation, various porosity was studied from 40 to 70% of porosity to reach suitable Young's Modulus. The etching parameters such as current density, time of porosification and electrolyte concentration were tuned to reach the desired porosity. Due to the patterning, the electrochemical etching occurred in 3 dimensions, the growth of porous start from all free lateral surfaces exposed by the pillar. Example parameters for the porosification process are shown in Table 1.

TABLE 1
Porosification parameters.

| Current | | | | |
|---|---|---|---|---|
| density | Electrolyte HF:Eth | | | |
| (mA/Cm²) | (Volume:Volume) | Mode | Porosity | Time (s) |
| 50 | 1:1 | Pulse | 40-45% | 60 |
| | | 1 s/1 s | | |
| 120 | 1:1 | Pulse | 50-55% | 35 |
| | | 1 s/1 s | | |
| 50 | 1:3 | direct | 70-75% | 150 |

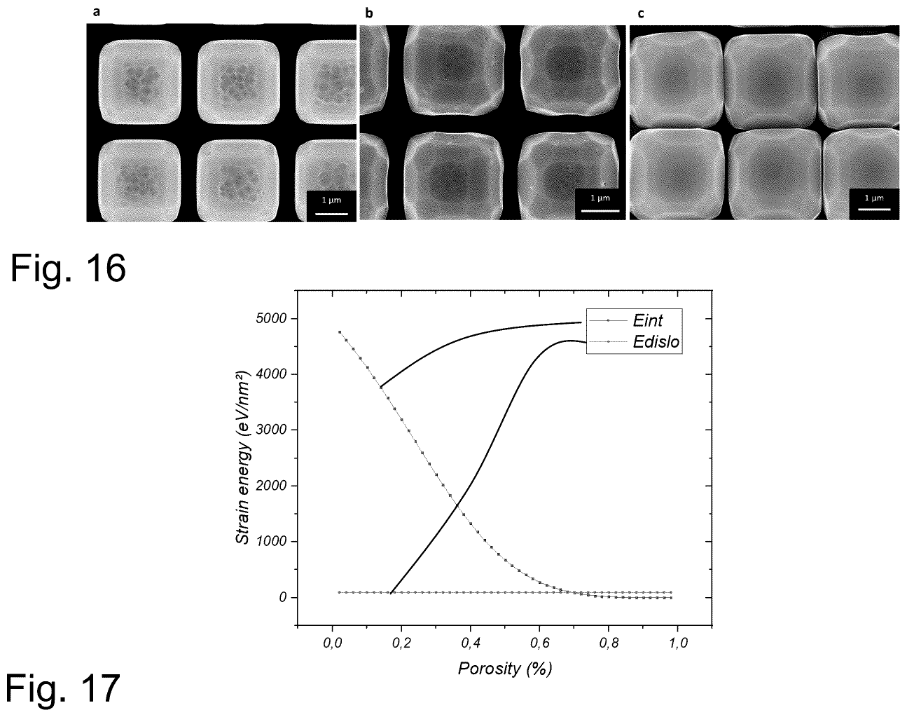

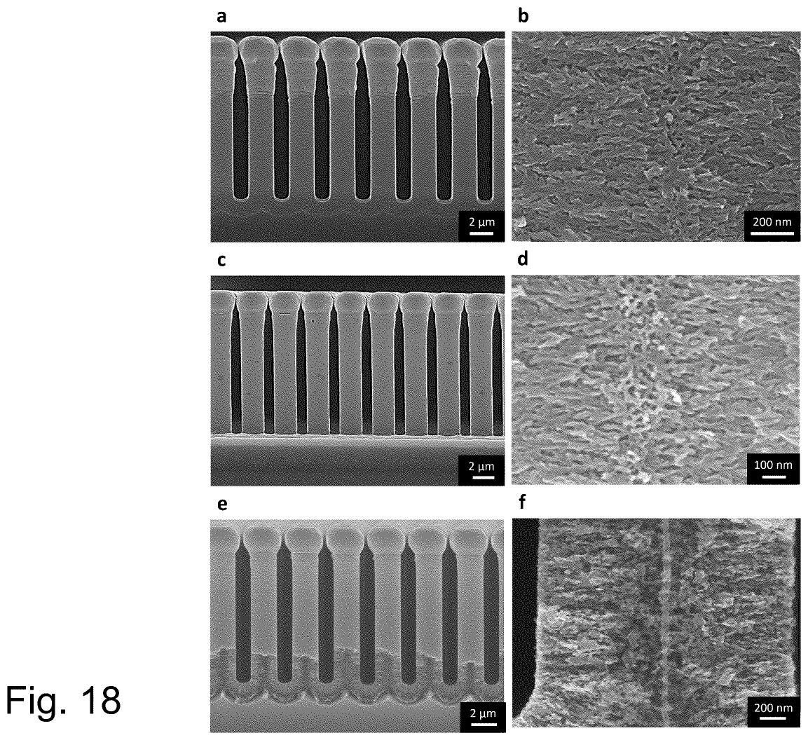

A full elastic strain accommodation should be accompanied by the absence of TDs. To validate this, etch-pit (EP) counting has been performed on both Ge epitaxial material deposited on SiP and PSiP. For this purpose, samples were immersed in a solution of two volumetric parts 49 wt % HF and 1 part 0.1 M K₂Cr₂O₇, where mixed and screw dislocations in the Ge material get selectively etched allowing their quantification by using plan view SEM observations. The average defect density has been extracted from different Ge/SiP and Ge/PSiP top-view SEM images. As shown by the FIG. 4a, relatively high TDD around 5.108 cm⁻² is found to reach the surface for Ge grown on SiP. Meanwhile, for Ge grown on PSiP, the surface appears completely free of pits implying that no TD dislocation reaches the surface (FIG. 4b). Bending of the towers can be observed in FIG. 4b due to the flexibility of the porous silicon pillars. To assess the impact of intermediate porosity on the TDD, Etch-pit counting on Ge microcrystals grown on 50% PSiP (FIG. 16) revealed that the TDD decreases down to 2.5 10⁸ cm⁻². The decrease of the threading dislocation density confirms that the crystalline quality of the Ge microcrystal's gets progressively improved with increasing the PSiP porosity.

The facet formation has been observed in all the investigated structures regardless the substrate preparation procedure as shown by the Top view SEM images (FIG. 16). In the meanwhile, the pillars porosification is found to induce faceting morphological changes. The difference in morphology can be attributed to the lack of a unique/dominant plan due to the porous template. The porous silicon pillars exhibit crystallites, each of them constitutes a nucleation site for Ge crystal resulting in a reduced area of <001>facet in favour of increasing that in the other crystallographic orientations. In some cases (see e.g., FIG. 4c) the microcrystals feature a rounded morphology. This is indeed expected in group IV crystallites at thermodynamic equilibrium. This result constitutes a first confirmation that the PSiP concept succeeds in accommodating the lattice mismatch strain. Obtaining such defect-fee microcrystals on a large-scale area, as shown by EP counting, by combining Bosch process, porosification and epitaxial growth, indicates that our method could potentially be scalable for industrial production.

As can be observed on the coupled scans (FIG. 8a,b), the full width at half maximum (FWHM) of the Ge peak grown on the porous structure is narrower than the one obtained with the reference on SiP, which confirms the improvement of the crystalline quality using such compliant substrate. Additionally, in case of Ge growth on PSiP an asymmetric broadening occurs for both Ge and Si diffraction peaks (FIG. 9) that evolves towards the formation of a plateau between Ge and Si peaks for a porosity of 70%. This phenomenon suggests a progressive accommodation of the lattice strain between both materials. Indeed, owing to the high porosity, the porous silicon pillars exhibit low Young's modulus allowing easy deformation to accommodate the lattice mismatch with the Ge microcrystals. Furthermore, the amount of diffused Ge, that may occur, into the PSiP is expected to increase with increasing the pillars' porosity and consequent decrease of the materials density. This phenomenon is expected to reduce the overall amount of pure Ge in the microcrystal and is likely to be the origin of the slight decrease of the Ge diffraction peaks intensity. Additionally, the Ge/Si intermixing mediated by porous Si reorganization during epitaxy can lead to the formation of Si₁₋ₓGeₓ alloy with graded composition that further contributes to reducing the lattice mismatch between the PSiP and the Ge microcrystal. Nonetheless, the well-known growth of graded layer is not enough to annihilate the lattice strain within only a few micrometers. In the present case, both phenomena, the porous structure deformation, and the interdiffusion of Si and Ge mediated by the porous structure, coexist giving rise to the observed elastic strain accommodation. While lower pillars porosities are expected to improve the Ge microcrystal's structural properties, full strain accommodation arises only when the porosity reaches 70% (FIG. 9) suggesting a threshold porosity that may vary depending on the epitaxial material. This highlight that the porosity constitutes a key parameter to accommodate the lattice mismatch strain. Moreover, as can be seen in literature, simultaneous reorganisation of both Ge and porous silicon can lead to decrease the TDD. High porosity combined with our low growth rate may favour this reorganization and thus the SiGe synthesis leading to the strain accommodation.

It's worth mentioning that based on the theory of compliance and discarding the Ge diffusion and consequent alloying effects, a simple analytical estimation of the areal strain energy associated with an isolated screw dislocation in Ge epitaxial layer on porous Si as a function of the porosity also predict an onset for full compliance around Si porosity of 68% (FIG. 17).

In order to assess the effect of porosity on TDD, we employed an analytical model allowing to determine the epilayer and dislocation energy evolution depending on the porosity. With such model we can predict, from the theory of compliance, what would be the ideal porosity required to avoid defect nucleation. The areal strain energy associated with an isolated screw dislocation is given by:

$$\\ \begin{matrix}{E}_{D} = \frac{{Gb}^{{}_{} 2}}{8 π \sqrt{2} a ( x )} ln ( \frac{h}{b} ) , & ( 4 )\end{matrix}$$

We first supposed an epitaxial layer grown on a compliant substrate with lattice mismatch strain f= (aₛ−aₑ)/aₑ, where f is the lattice mismatch strain existing in a coherently strain epilayer, aₛ and aₑ are respectively the lattice parameter of the substrate and epitaxial layer. In our case we did not consider the curvature at the interface between materials.

Without such curvature, the compliant substrate and the epilayer (microcrystal) are oppositely strained: εₑₚᵢ−ε_{sub}=f, where εₑₚᵢ and ε_{sub} represent respectively the in-plane strains in the microcrystal and the substrate. Force balance requires that: σₑₚᵢhₑₚᵢ+σ_{sub}h_{sub}=0, where hₑₚᵢ and h_{sub} are the thickness of the microcrystal and substrate respectively, and σₑₚᵢ and σ_{sub} are the in-plane stresses. The shear modulus of the porous silicon Gₚ and its Poisson's ratio νₚ can be described by the following empirical rules:

$$\\ \begin{matrix}{G}_{p} = {G ( 1 - P )}^{4} , & ( 5 )\end{matrix}$$

$$\\ \begin{matrix}{v}_{p} = v ( 1 - P ) , & ( 6 )\end{matrix}$$

where G and v are respectively the shear modulus and Poisson's ration of silicon and P the porosity. Considering the elastic constant K, stress can be related to strain as follows:

$$\\ \begin{matrix}{σ}_{epi} = {K}_{epi} {ε}_{epi} , & ( 7 )\end{matrix}$$

$$\\ \begin{matrix}{σ}_{sub} = {K}_{sub} {ε}_{sub} , with & ( 8 )\end{matrix}$$

$$\\ \begin{matrix}{K}_{epi} = 2 {G}_{epi} \frac{( 1 + {v}_{epi} )}{( 1 - {v}_{epi} )} , and {K}_{sub} = 2 {G}_{p} \frac{( 1 + {v}_{p} )}{( 1 - {v}_{p} )} . & ( 9 )\end{matrix}$$

The strain accumulated in the epilayer (Ge microcrystal) will be equal to:

$$\\ \begin{matrix}{ε}_{epi} = f \frac{{K}_{sub} {h}_{sub}}{{K}_{sub} {h}_{sub} + {K}_{epi} {h}_{epi}} . & ( 10 )\end{matrix}$$

And the elastic energy stored per unit area of the interface can be defined as:

$$\\ \begin{matrix}{E}_{int} = \frac{{K}_{epi} {h}_{epi} {K}_{sub} {h}_{sub}}{{K}_{epi} {h}_{epi} + {K}_{sub} {h}_{sub}} {f}^{{}_{} 2} . & ( 11 )\end{matrix}$$

As we can observe in FIG. 17, the porosity required to avoid defect nucleation (the strain energy accumulated in the epilayer being inferior to the energy of a dislocation) is around 68%.

The porous Si structure undergoes morphological transformation to reduce its total surface energy, due to the thermal budget provided during Ge epitaxial growth following the Ostwald ripening process. Accordingly, during thermal annealing the Si atoms on the surface of the pores move to energetically favourable positions, leaving Si-free volume into the center of the pillars.

As can be understood, the examples described above and illustrated are intended to be exemplary only. The scope is indicated by the appended claims.

What is claimed is:

1. A method of manufacturing a semiconductor heterostructure, the method comprising:
depositing an epitaxial layer of a first material atop a crystalline substrate, the crystalline substrate having a porous layer of a second material, the porous layer having a pore density above a pore density threshold, the second material different from the first material;
heating the semiconductor heterostructure above a temperature threshold; and
said depositing and said heating diffusing atoms of the first material across the crystalline substrate and into the porous layer, the atoms of the first material at least partially filling voids of the porous layer thereby relieving strain existing between the first material of the epitaxial layer and the second material of the porous layer.

2. The method of claim 1 wherein said filling includes forming a strain relieving alloy with the second material of the porous layer of the crystalline substrate.

3. The method of claim 1 wherein the temperature threshold ranges between about 50° C. and about 1400° C.

4. The method of claim 1 wherein the pore density ranges between about 15% and 90%, the pore density defined as a volume of void over a volume of the porous layer.

5. The method of claim 1 wherein said heating is performed simultaneously to said depositing.

6. The method of claim 1 wherein said depositing is performed during a first period of time, and said heating is performed during a second period of time subsequent to the first period of time.

7. The method of claim 1 wherein said porous layer includes a plurality of microstructures distributed within the porous layer.

8. The method of claim 7 wherein said plurality of microstructures is provided in the form of a plurality of micropillars extending at least partially perpendicularly to a plane of the crystalline substrate.

9. The method of claim 1 wherein the crystalline substrate includes a semiconductor material of one of a group IV element, a group III-V element, a group II-VI element, and a group III-N element, the first material being a semiconductor material of one of a group IV element, a group III-V element, a group II-VI element, and a group III-N element, and the second material being a semiconductor material of one of a group IV element, group III-V element, a group II-VI element, and a group III-N element.

10. The method of claim 1 wherein the crystalline substrate is silicon-based, the first material is germanium-based and the second material is silicon-based.

11. The method of claim 1 further comprising, prior to said depositing, deoxidizing the crystalline substrate, said deoxidizing including chemically deoxidizing the crystalline substrate using a solution having hydrofluoric acid and ethanol.

12. The method of claim 1 further comprising, prior to said depositing, covering the crystalline substrate with a graphene layer, said covering being performed at a temperature ranging between about 300° C. and about 1000° C.

13. A semiconductor heterostructure comprising: an epitaxial layer of a first material received atop a crystalline substrate, the crystalline substrate having a porous layer of a second material, the porous layer having a pore density above a pore density threshold, the second material different from the first material, voids of the porous layer being at least partially filled with atoms of the first material thereby relieving strain existing between the first material of the epitaxial layer and the second material of the porous layer.

14. The semiconductor heterostructure of claim 13 wherein the porous layer includes a strain relieving alloy formed with the second material and the first material.

15. The semiconductor heterostructure of claim 13 wherein the pore density ranges between about 15% and 90%, the pore density defined as a volume of void over a volume of the porous layer.

16. The semiconductor heterostructure of claim 13 wherein said porous layer includes a plurality of microstructures distributed within the porous layer.

17. The semiconductor heterostructure of claim 16 wherein said plurality of microstructures is provided in the form of a plurality of micropillars extending at least partially perpendicularly to a plane of the crystalline substrate.

18. The semiconductor heterostructure of claim 13 further comprising a buffer layer of a semiconductor material sandwiched between the crystalline substrate and the epitaxial layer.

19. The semiconductor heterostructure of claim 13 wherein the crystalline substrate includes a semiconductor material of one of a group IV element, a group III-V element, a group II-VI element, and a group III-N element, the first material being a semiconductor material of one of a group IV element, a group III-V element, a group II-VI element, and a group III-N element, and the second material being a semiconductor material of one of a group IV element, group III-V element, a group II-VI element, and a group III-N element.
